(19) United States
(12) Patent Application Publication
(10) Pub. No.: US 2022/0140040 A1
(43) Pub. Date: May 5, 2022

(54) DISPLAY PANEL, MANUFACTURING METHOD THEREOF AND DISPLAY DEVICE

(71) Applicant: BOE TECHNOLOGY GROUP CO., LTD., Beijing (CN)

(72) Inventors: Jiahao ZHANG, Beijing (CN); Haoran WANG, Beijing (CN); Penghao GU, Beijing (CN); Song ZHANG, Beijing (CN)

(73) Assignee: BOE TECHNOLOGY GROUP CO., LTD., Beijing (CN)

(21) Appl. No.: 16/955,363

(22) PCT Filed: Jun. 28, 2019
(86) PCT No.: PCT/CN2019/093747

§ 371 Date: Jun. 18, 2020

(51) Int. Cl. H01L 27/32; H01L 51/52; H01L 51/56

(52) U.S. Cl. CPC H01L 27/3272; H01L 27/3234; H01L 2227/323; H01L 51/5253; H01L 51/56; H01L 27/326

(57) ABSTRACT

A display panel, a manufacturing method thereof and a display device are disclosed. The display panel includes a display array layer, a first optical structural layer, and a first light shielding pattern. The display array layer includes a first sub-display area and a second sub-display area at least partially surrounded by the first sub-display area, the second sub-display area is configured to be able to transmit ambient light; the first optical structural layer is located at a display side of the display array layer; and the first light shielding pattern is located at a side of the first optical structural layer facing the display array layer, and the first light shielding pattern at least partially surrounds the second sub-display area and exposes at least a part of the second sub-display area.

### TECHNICAL FIELD

At least an embodiment of the present disclosure provides a display panel, a manufacturing method thereof and a display device.

### BACKGROUND

With a development and progress of the society, an electronic display product has more and more widespread applications, and users have increasing requirements for the display effect of electronic display products. Generally, a current electronic display product is provided therein with a camera, and in order to pursue a narrow bezel to obtain a better display effect, the camera may be provided below a display screen to obtain an under-screen camera structure. However, when the under-screen camera structure works, light generated by the display screen is reflected in the display screen into the camera and interferes with the function of the camera.

### SUMMARY

At least an embodiment of the present disclosure provides a display panel, comprising: a display array layer comprising a first sub-display area and a second sub-display area at least partially surrounded by the first sub-display area, the second sub-display area being configured to be able to transmit ambient light; a first optical structural layer located at a display side of the display array layer; and a first light shielding pattern located at a side of the first optical structural layer facing the display array layer, wherein the first light shielding pattern at least partially surrounds the second sub-display area and exposes at least a part of the second sub-display area.

For example, in the display panel according to at least one embodiment of the present disclosure, the first light shielding pattern is located between the display array layer and the first optical structural layer in a direction perpendicular to a plane where the display array layer is located.

For example, in the display panel according to at least one embodiment of the present disclosure, the display array layer comprises a plurality of sub-pixels spaced apart from each other; and the first light shielding pattern at least partially overlaps with a spacing area between adjacent sub-pixels in the direction perpendicular to the plane where the display array layer is located.

For example, in the display panel according to at least one embodiment of the present disclosure, in the second sub-display area, the first light shielding pattern further comprises a net-shaped light shielding bar; and at the plane where the display array layer is located, an orthogonal projection of a net-shaped portion of the light shielding bar coincides with an orthogonal projection of the spacing area between adjacent sub-pixels, and an orthogonal projection of a mesh hole of the light shielding bar coincides with an orthogonal projection of the sub-pixel.

For example, in the display panel according to at least one embodiment of the present disclosure, the first optical structural layer comprises an optical film.

For example, in the display panel according to at least one embodiment of the present disclosure, the optical film comprises a quarter-wave plate and/or a polarizer.

For example, the display panel according to at least one embodiment of the present disclosure further comprises: an encapsulation layer located between the display array layer and the first optical structural layer; wherein the first light shielding pattern is located between the encapsulation layer and the first optical structural layer, or located between the display array layer and the encapsulation layer.

For example, the display panel according to at least one embodiment of the present disclosure further comprises: a first optical adhesive layer located between the encapsulation layer and the optical film; wherein the first light shielding pattern is located between the first optical adhesive layer and the encapsulation layer, or located between the first optical adhesive layer and the optical film.

For example, in the display panel according to at least one embodiment of the present disclosure, the first optical adhesive layer has a thickness not less than a thickness of the first light shielding pattern.

For example, in the display panel according to at least one embodiment of the present disclosure, the thickness of the first optical adhesive layer is at least four times the thickness of the first light shielding pattern.

For example, in the display panel according to at least one embodiment of the present disclosure, the first light shielding pattern is located at a side of the display array layer opposite to the first optical structural layer in a direction perpendicular to the plane where the display array layer is located.

For example, in the display panel according to at least one embodiment of the present disclosure, a plurality of openings are provided in a portion of the first light shielding pattern, which portion is located in the second sub-display area.

For example, the display panel according to at least one embodiment of the present disclosure further comprises a black matrix, wherein at least a part of the black matrix is located in the first sub-display area at a side of the first optical structural layer opposite to the display array layer.

At least one embodiment of the present disclosure provides a display device, comprises any one of the above-mentioned display panels.

The display device according to at least one embodiment of the present disclosure claim 14 further comprises an image taking device, the image taking device is located at a side of the display panel opposite to the display side; and at a plane where the display panel is located, an orthographic projection of the second sub-display area of the display panel at least partially overlaps with an orthographic projection of the image taking device.

At least one embodiment of the present disclosure provides a manufacturing method of a display panel, comprising: forming a display array layer comprising a first sub-display area and a second sub-display area at least partially surrounded by the first sub-display area, wherein the second sub-display area is formed to be able to transmit ambient light; forming a first optical structural layer at a display side of the display array layer; and forming a first light shielding pattern at a side of the first optical structural layer facing the display array layer, wherein the first light shielding pattern is formed to at least partially surround the second sub-display area and expose at least a part thereof.

For example, in the manufacturing method according to at least one embodiment of the present disclosure, the formed display array layer comprises a plurality of spaced sub-pixels, and forming the first light shielding pattern comprises: forming a net-shaped light shielding bar in the second sub-display area; wherein at a plane where the display array layer is located, an orthogonal projection of a net-shaped portion of the light shielding bar coincides with an orthogonal projection of a spacing area between adjacent sub-pixels, and an orthogonal projection of a mesh hole of the light shielding bar coincides with an orthogonal projection of the sub-pixel.

For example, the manufacturing method according to at least one embodiment of the present disclosure further comprises: forming an encapsulation layer at a surface of the display side of the display array layer; wherein the encapsulation layer is located between the display array layer and the first optical structural layer.

For example, in the manufacturing method according to at least one embodiment of the present disclosure, forming the first light shielding pattern comprises: applying a light shielding material on the encapsulation layer to form the first light shielding pattern, and then providing a first optical adhesive layer to attach the first optical structural layer on the encapsulation layer; or applying a light shielding material at a side of the first optical structural layer to form the first light shielding pattern, and then providing a first optical adhesive layer to attach the first optical structural layer on the encapsulation layer.

For example, in the manufacturing method according to at least one embodiment of the present disclosure, a method of applying the light shielding material comprises a screen printing method.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1A is a plan view of a display panel according to some embodiments of the present disclosure;

FIG. 1B is a sectional view of the display panel shown in FIG. 1A along line A-B;

FIG. 1C is a schematic diagram of an arrangement relationship between a first light shielding pattern and sub-pixels in the display panel shown in FIG. 1B;

FIG. 1D is a schematic diagram of another arrangement relationship between a first light shielding pattern and sub-pixels in the display panel shown in FIG. 1B;

FIG. 1E is a plan view of the first light shielding pattern shown in FIG. 1D;

FIG. 2A is a sectional view of another display panel according to some embodiments of the present disclosure;

FIG. 2B is a plan view of a first light shielding pattern in the display panel shown in FIG. 2A;

FIG. 3 is a sectional view of another display panel according to some embodiments of the present disclosure;

FIG. 4 is a sectional view of another display panel according to some embodiments of the present disclosure;

FIG. 5A is a sectional view of another display panel according to some embodiments of the present disclosure;

FIG. 5B is a plan view of a first light shielding pattern in the display panel shown in FIG. 5A;

FIG. 6 is a sectional view of another display panel according to some embodiments of the present disclosure;

FIG. 7A is a sectional view of a display device according to some embodiments of the present disclosure;

FIG. 7B is a sectional view of another display device according to some embodiments of the present disclosure; and

FIGS. 8A-8C are process charts of a manufacturing method of a display panel according to some embodiments of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

For example, in some electronic display products with an image taking function, a camera may be provided under a display panel, for example, provided to overlap with a display area of a display panel (for example, an OLED). That is, an under-screen camera structure is provided, thereby facilitating implementation of a narrow bezel of the display panel and thus realization of full-screen display.

Usually, a display side of the display panel is provided with a multilayer structure for encapsulation, improvement in a display effect, or the like; and due to the interfaces caused by the difference in refractive index between respective components (layers) in the multilayer structure, or the like, light generated in the display panel is unable to be transmitted through the multilayer structure completely, and a part of the light may be reflected at the interfaces between the components of the multilayer structure. That is, the reflected light may be propagated towards a side of the display panel opposite to the display side. Therefore, in the display process of the electronic display product with the under-screen camera structure, if the image taking function is activated, the above-mentioned reflected light generated in an area of the display panel adjacent to the camera (area overlapping with the camera and/or area adjacent to the overlapping area) is incident into the camera, resulting in a “ghost” phenomenon of the image taken by the camera (i.e., the phenomenon that the image obtained by the camera is mixed with a part of an image displayed by the display panel itself), such that the image obtained by the camera has a poor quality.

At least one embodiment of the present disclosure provides a display panel, a manufacturing method thereof and a display device. The display panel includes a display array layer, a first optical structural layer, and a first light shielding pattern. The display array layer includes a first sub-display area and a second sub-display area at least partially surrounded by the first sub-display area, the second sub-display area is configured to be able to transmit ambient light; the first optical structural layer is located at a display side of the display array layer; and the first light shielding pattern is located at a side of the first optical structural layer facing the display array layer, and the first light shielding pattern at least partially surrounds the second sub-display area and exposes at least a part of the second sub-display area.

In the display panel, the first light shielding pattern can shield a part of light (interference light) which is generated in an area of the first sub-display area adjacent to the second sub-display area and reflected by the first optical structural layer to the second sub-display area, so as to prevent the interference light from being emitted out from a side of the display panel opposite to a display side in the second sub-display area of the display panel, or to reduce the amount of the interference light emitted out from the side opposite to the display side in the second sub-display area of the display panel. In the presence of an image taking device, ambient light (including light of a shot object) may enter the image taking device through the second sub-display area, and the above-mentioned interference light is not emitted into the image taking device or the amount of the light that is emitted into the image taking device is small, thereby improving the quality of an image taken by the image taking device.

In the present disclosure, “transmittance of ambient light” may be selected to 20% or more as required, and in embodiments, may be 50%, 70%, 90%, or the like, thereby correspondingly allowing an image with the required quality to be taken by the image taking device; the same will be applied hereinafter and not repeated herein.

The display panel, the manufacturing method thereof and the display device according to at least one embodiment of the present disclosure will be described below with reference to the accompanying drawings.

In the at least one embodiment, the side of the display panel opposite to the display side is configured as a back side of the display panel. Furthermore, a space rectangular coordinate system in which the X axis and the Y axis are parallel to a plane where the display array layer is located and the Z axis is perpendicular to the plane where the display array layer is located is established with reference to the display array layer, so as to explain positions of respective components in the display panel.

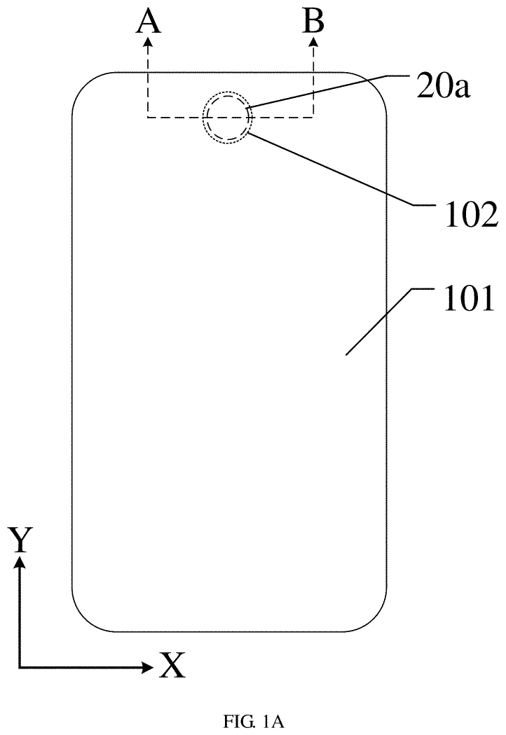

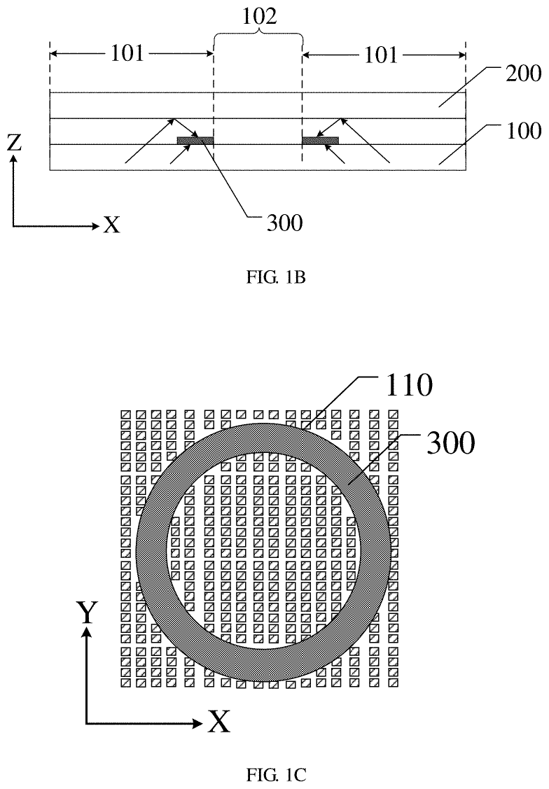

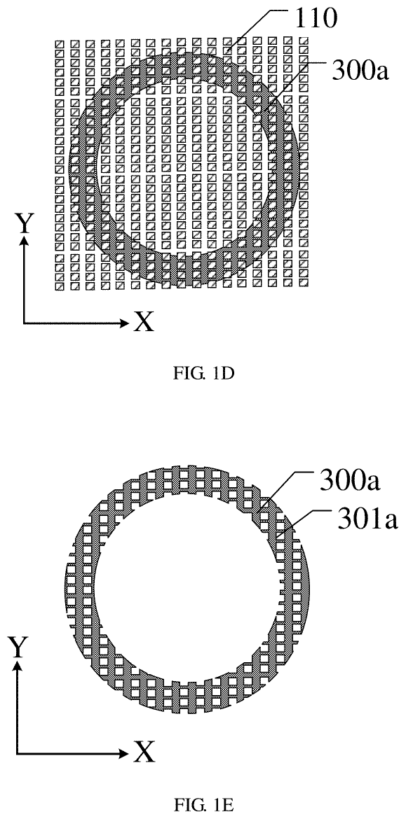

In the display panel according to at least one embodiment of the present disclosure, as shown in FIGS. 1A and 1B, the display array layer 100 includes a first sub-display area 101 and a second sub-display area 102 surrounded by the first sub-display area 101, a first optical structural layer 200 is located at a display side (light outgoing side) of the display array layer 100, and a first light shielding pattern 300 is located at a side of the first optical structural layer 200 facing the display array layer 100, and may at least partially (the portion as shown in FIG. 1B) surround the second sub-display area 102 and expose at least a part of the second sub-display area 102.

It should be noted that the surrounding state in the present disclosure may be a non-closed surrounding state or closed surrounding state, so as to reduce the emission of interference light from the side of the display panel opposite to the display side in the second sub-display area of the display panel.

In some examples, the first light shielding pattern 300 partially surrounds the second sub-display area 102 in a non-closed manner, or may completely surround the second sub-display area 102 in a closed manner and expose at least a part of the second sub-display area 102.

For example, in FIG. 1B, the first light shielding pattern 300 exposes the entire second sub-display area 102. That is, the first light shielding pattern 300 is located in the first sub-display area 101. For example, the second sub-display area 102 is configured to be able to transmit ambient light, and the configuration may be designed according to specific structural and technological requirements of the display panel, as described in the following embodiments.

According to the above-mentioned design, the interference light (indicated by an arrow in FIG. 1B) generated by a portion of the display array layer 100 located in the first sub-display area 101 and adjacent to the second sub-display area 102 can be shielded by the first light shielding pattern 300 and is unable to be emitted out from the back side of the display panel.

It should be noted that in at least one embodiment of the present disclosure, as long as the area of the first sub-display area adjacent to the second sub-display area (i.e., a periphery of the second sub-display area) is provided with the first light shielding pattern, the amount of the interference light emitted out from the back side of the display panel can be reduced, and a size, a shape and a distribution of the first light shielding pattern in other areas of the display panel (for example, the second sub-display area) may be designed according to actual needs and are not limited herein.

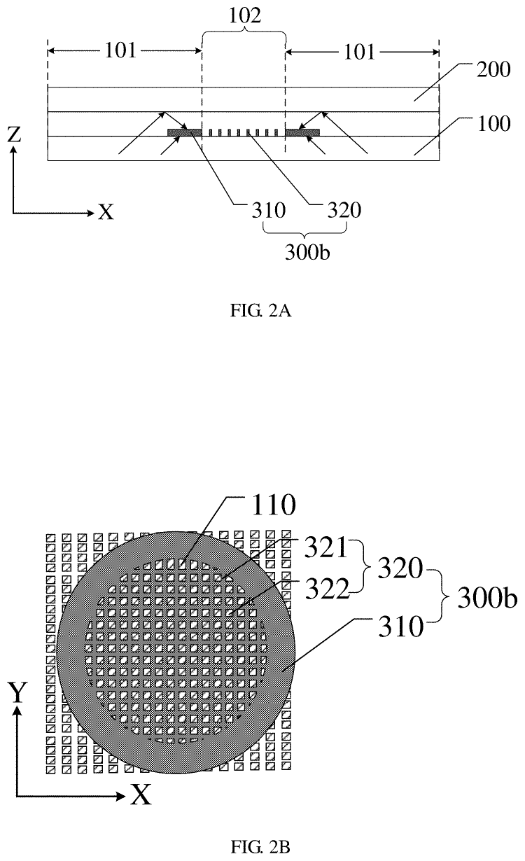

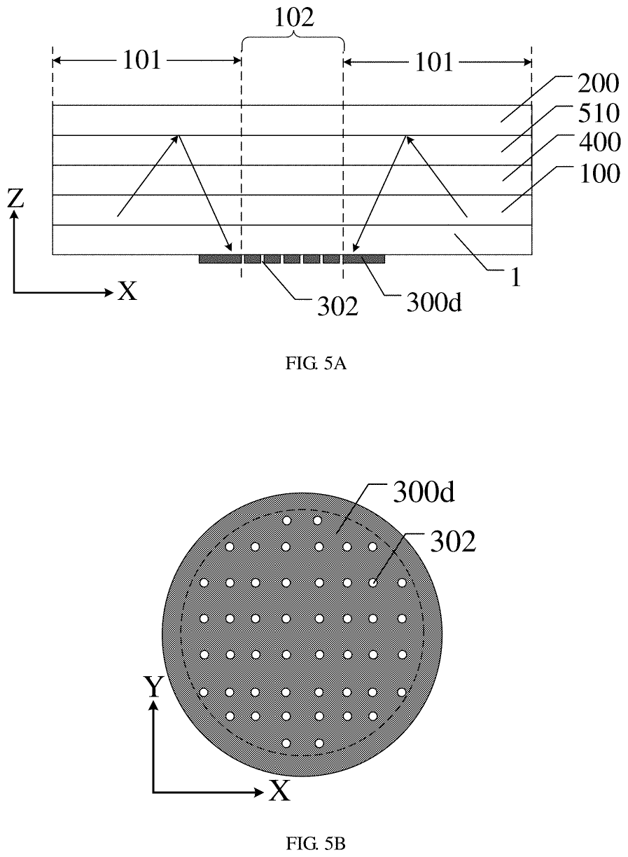

For example, in some embodiments of the present disclosure, the first light shielding pattern may be located in the first sub-display area (for example, refer to the embodiments shown in FIGS. 1B, 3 and 4), so as to prevent the interference light generated by the first sub-display area from entering the second sub-display area, and thus prevent the interference light from being emitted out from the back side of the display panel; for example, in some other embodiments of the present disclosure, the first light shielding pattern may have one part located in the first sub-display area and the other part located in the second sub-display area (for example, refer to the embodiments shown in FIGS. 2A and 5A), so as to prevent the interference light generated by the first sub-display area and incident into the second sub-display area from being emitted out from the back side of the display panel.

The different distribution of the first light shielding pattern in the first sub-display area and the second sub-display area is related to the relationship of positions between the first light shielding pattern and the display array layer in a direction perpendicular to the plane where the display array layer is located. Several design structures of the first light shielding pattern are explained below in the direction perpendicular to the plane where the display array layer is located, in conjunction with different position relationships between the first light shielding pattern and the display array layer.

For example, in the display panel according to at least one embodiment of the present disclosure, the first light shielding pattern is located between the display array layer and the first optical structural layer in the direction perpendicular to the plane where the display array layer is located. Exemplarily, as shown in FIG. 1B, the first light shielding pattern 300 is provided between the display array layer 100 and the first optical structural layer 200, and thus can absorb one part of the interference light reflected by the first optical structural layer 200 and can further absorb the other part of the interference light emitted from the display array layer to the first optical structural layer 200. That is, the other part of the light does not reach the first optical structural layer 200.

For example, in the display panel according to some embodiments of the present disclosure, as shown in FIG. 1C, the first light shielding pattern 300 is located in the first sub-display area 101. For example, the first light shielding pattern 300 has a closed loop shape to define the second sub-display area 102 of the display panel as shown in FIG. 1B. That is, an orthogonal projection of an opening of the loop shape at the display array layer 100 coincides with an orthogonal projection of the second sub-display area 102 at the display array layer 100. Thus, in any direction around the second sub-display area 102, the first light shielding pattern 300 may shield the interference light generated by the first sub-display area 101 to reduce the amount of the interference light emitted out from the back side of the display panel.

For example, in the display panel according to at least one embodiment of the present disclosure, the display array layer includes a plurality of sub-pixels spaced apart from each other. For example, in some embodiments of the present disclosure, the sub-pixels are located in the first sub-display area. For example, in some other embodiments of the present disclosure, both the first and second sub-display areas are provided with sub-pixels. Thus, in the case where an image taking device is provided at the back side of the display panel, an image may be displayed in the second sub-display area of the display panel while the image taking function is performed.

For example, in at least one embodiment of the present disclosure, in the case where the first light shielding pattern is located between the display array layer and the first optical structural layer, the first light shielding pattern at least partially overlaps with a spacing area of the adjacent sub-pixels in the direction perpendicular to the plane where the display array layer is located. For example, an orthographic projection of the first light shielding pattern at the plane where the display array layer is located is located within an orthographic projection of the spacing area between adjacent sub-pixels at the plane where the display array layer is located, and thus, the display function of the display panel may not be influenced by the arrangement of the first light shielding pattern.

For example, in some embodiments of the present disclosure, as shown in FIG. 1C, the arrangement of the sub-pixels 110 is adjusted; and in the first sub-display area, no sub-pixel 110 is provided in an area where the first light shielding pattern 300 is located. Thus, the first light shielding pattern 300 has a large design area, with a good shielding effect on the interference light.

For example, in some other embodiments of the present disclosure, as shown in FIGS. 1D and 1E, the arrangement of the sub-pixels 110 may not be adjusted, and a portion of the first light shielding pattern 300a overlapping with the sub-pixel 110 is configured as a first opening 301a. That is, in the area provided with the first light shielding pattern 300a, an orthographic projection of the first opening 301a at the plane where the display array layer is located coincides with an orthographic projection of the sub-pixel 110 at the plane where the display array layer is located. Thus, the arrangement of the first light shielding pattern 300a has no influence on the arrangement of the sub-pixels 110, the display panel has a large number of sub-pixels, and a high resolution is kept.

For example, in the display panel according to at least one embodiment of the present disclosure, in the second sub-display area, the first light shielding pattern further includes a light shielding bar having a net shape, and at the plane where the display array layer is located, an orthogonal projection of a net-shaped portion of the light shielding bar coincides with an orthogonal projection of the spacing area between adjacent sub-pixels, and an orthogonal projection of a mesh hole of the light shielding bar coincides with an orthogonal projection of the sub-pixel.

Exemplarily, as shown in FIGS. 2A and 2B, the first light shielding pattern 300b includes an annular portion 310 and a net-shaped portion 320. For the annular portion 310, reference may be made to the relevant design of the first light shielding pattern in the foregoing embodiments (for example, the embodiments shown in FIGS. 1C and 1E), and description thereof is not repeated herein. The net-shaped portion 320 includes a plurality of light shielding bars 321 which cross each other to form a plurality of mesh holes 322. The orthographic projection of the mesh holes 322 at the plane where the display array layer 100 is located coincides with the orthographic projection of the sub-pixel 110 at the plane where the display array layer 100 is located. Thus, the first light shielding pattern 300 may have a design area which is further increased; furthermore, the first light shielding pattern 300 can also shield the interference light emitted by the sub-pixel 110 in the second sub-display area 102 and reflected by the first optical structural layer 200, thereby further reducing the amount of the interference light emitted from the back side of the display panel.

For example, in at least one embodiment of the present disclosure, in the case where the first light shielding pattern is annular (as shown in FIG. 1C) or includes an annular portion (as shown in FIG. 2B), the inner side and the outer side of the annular shape are spaced apart by no more than 1 mm, and thus, human eyes have difficulty in distinguishing the existence of the first light shielding pattern in visual effect during display of the display panel, thereby guaranteeing the good display effect of the display panel. For example, the second sub-display area defined by the annular shape may have a diameter of 1 to 5 mm, for example, 1 to 3 mm. The diameter of the second sub-display area may be designed according to actual needs, such as the size of the image taking device, and is not limited to the above-mentioned range.

In at least one embodiment of the present disclosure, in the case where the first light shielding pattern is located between the display array layer and the first optical structural layer, how to configure the second sub-display area of the display panel to transmit the ambient light is not limited in different solutions in which the above-mentioned first light shielding pattern is located in the first sub-display area or in both the first and second sub-display areas.

Exemplarily, each sub-pixel of the display array layer includes a light-emitting device including an anode, a light-emitting functional layer and a cathode which are sequentially stacked from the back side to the display side of the display panel. For example, the anodes of the plurality of sub-pixels are spaced apart from each other and arranged in an array. For example, the display array layer further includes a drive circuit layer to drive the light-emitting device to emit light. For example, the drive circuit layer may include a pixel drive circuit including a plurality of transistors, a capacitor, a light-emitting device, or the like, for example, in various forms, such as 2T1C (i.e., 2 transistors (T) and 1 capacitor (C)), 3T1C, 7T1C, or the like. The structure, composition, or the like, of the drive circuit layer are limited in the embodiments of the present disclosure.

For example, in the case where the first light shielding pattern is located in the first sub-display area as shown in FIG. 1B, the anode may be configured as a reflective electrode (in a single-layer or multilayer structure) to enable light generated by the light-emitting device to be emitted out towards the display side of the display panel, and thus, in the second sub-display area, the ambient light may be transmitted through gaps between the plurality of sub-pixels (i.e., gaps between the plurality of anodes) and thus transmitted through the display panel to exit from the back side of the display panel; alternatively, the display array layer may include a reflective layer located at a side of the light-emitting device opposite to the first optical structural layer, such that the anode is not required to be configured as the reflective electrode itself, and in the second sub-display area, the portion of the reflective layer located at the spacing area between adjacent sub-pixels (for example, a portion not overlapping with the anode of the sub-pixel) is removed, such that the ambient light may be transmitted through the gaps between the plurality of sub-pixels and thus transmitted through the display panel to exit from the back side of the display panel. For example, the sub-pixels in the second sub-display area may have an arrangement density less than the sub-pixels in the first sub-display area, such that the sub-pixels in the second sub-display area have a large spacing, thereby increasing the transmittance of the ambient light.

For example, in the case where the first light shielding pattern is located at both the first and second sub-display areas as shown in FIG. 2A, a partial area of the sub-pixel may be configured to transmit light in the second sub-display area. For example, in the case where the anode may be configured as the reflective electrode, the anode of the second sub-display area may be provided with a plurality of holes, the portion of the light-emitting functional layer corresponding to the holes may not emit light, and the hole may transmit the ambient light.

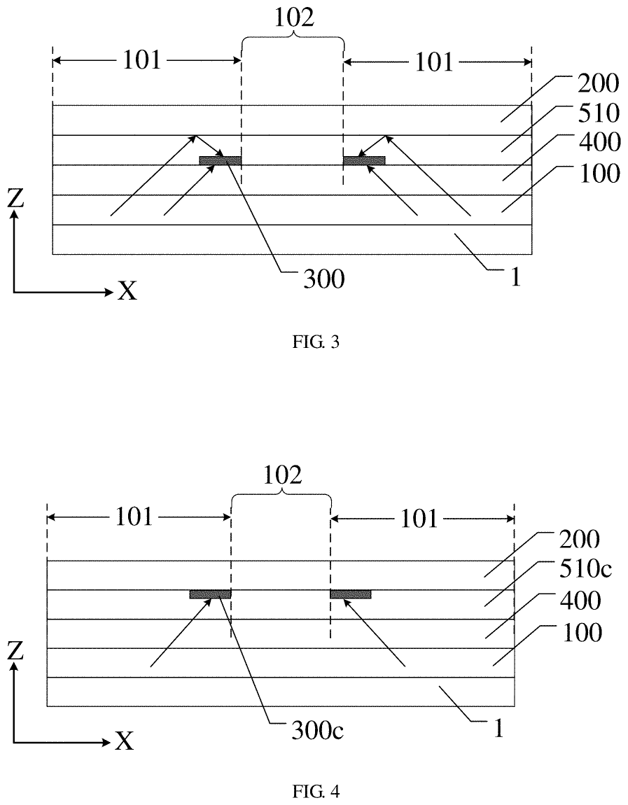

For example, according to at least one embodiment of the present disclosure, the display panel may further include an encapsulation layer located between the display array layer and the first optical structural layer. Exemplarily, as shown in FIG. 3, the encapsulation layer 400 covers the display array layer 100 to prevent external water, oxygen, or the like, from entering the display array layer 100, thereby protecting elements (for example, the light-emitting devices, or the like) in the display array layer 100.

For example, the encapsulating layer may have a single-layer structure or a composite structure including at least two layers. For example, the encapsulation layer may be made of an insulating material, such as silicon nitride, silicon oxide, silicon oxynitride, a high molecular resin, or the like. For example, the encapsulation layer may include a first inorganic encapsulation layer, an organic encapsulation layer, and a second inorganic encapsulation layer which are sequentially provided on the light-emitting device. For example, the first and second inorganic encapsulation layers may be made of an inorganic material, such as silicon nitride, silicon oxide, silicon oxynitride, or the like, which has high compactness to prevent the intrusion of water, oxygen, or the like; for example, the organic encapsulation layer may be made of a high molecular material containing a desiccant, a high molecular material blocking moisture, or the like, such as a high molecular resin, or the like, so as to planarize the surface of the display substrate and relieve the stress in the first and second inorganic encapsulation layers, and the organic encapsulation layer may further include a water-absorbing material, such as a desiccant, or the like, so as to absorb substances, such as the water, the oxygen, or the like, which have intruded into the encapsulation layer.

For example, in the display panel according to some embodiments of the present disclosure, as shown in FIG. 3, the first light shielding pattern 300 may be located between the encapsulation layer 400 and the first optical structural layer 200. Thus, the encapsulation layer 400 can prevent harmful substances in the first light shielding pattern 300 (for example, the first light shielding pattern 300 is made of ink) from intruding into the display array layer 100.

For example, in the display panel according to some other embodiments of the present disclosure, the first light shielding pattern is located between the display array layer and the encapsulation layer. Thus, the encapsulation layer can eliminate the step caused by the arrangement of the first light shielding pattern, and facilitate planarization of the display panel, and the design thickness of the first light shielding pattern may be not limited. For example, the display array layer includes a pixel defining layer including a plurality of openings in which the light-emitting devices are located. For example, the first light shielding pattern is located on the pixel defining layer. That is, the first light shielding pattern is located between the pixel defining layer and the encapsulation layer.

Hereinafter, in the case where the first light shielding pattern is located between the display array layer and the first optical structural layer, the technical solution in at least one of the following embodiments of the present disclosure will be explained with the case where the first light shielding pattern is located between the encapsulation layer and the first optical structural layer as an example.

For example, in the display panel according to at least one embodiment of the present disclosure, the type of the first optical structural layer is not limited, and the first optical structural layer may include any film layer which is located at the light outgoing side of the display array layer and may reflect light partially. For example, the first optical structural layer includes an optical film. It should be noted that generally, both sides of the optical film (for example, a polarizer) are provided with adhesive layers, such as pressure sensitive adhesives (PSA), such that an optical adhesive layer (for example, optically clear adhesive (OCA)) for fixing the optical film is not required to be formed additionally when the display panel is assembled. Compared with an optical adhesive layer which is applied in the display panel separately, the pressure sensitive adhesive has a less thickness and a less usage amount, which facilitates the lightness and thinness of the display panel, and the pressure sensitive adhesive may be used for eliminating the step to achieve a planarization effect, which facilitates improvement in flatness of the display panel. For example, the above-mentioned pressure sensitive adhesive may be made of a resin type material, such as polyurethane, polyacrylate, silicone, or the like, or a rubber type material to have a high light transmittance.

For example, the display panel according to at least one embodiment of the present disclosure further includes a first optical adhesive layer located between the encapsulation layer and the optical film. Exemplarily, as shown in FIG. 3, the first optical adhesive layer 510 is located on the display array layer. For example, in the case where the first optical structural layer includes the optical film, the first optical adhesive layer may be configured as an adhesive layer, such as a pressure sensitive adhesive, carried by the optical film.

For example, in the display panel according to some other embodiments of the present disclosure, the first light shielding pattern is located between the first optical adhesive layer and the display array layer. Exemplarily, as shown in FIG. 3, the first light shielding pattern 300 is located between the first optical adhesive layer 510 and the encapsulation layer 400. Thus, when the display panel is manufactured, after the first light shielding pattern 300 is formed on the encapsulation layer 400, the optical film (the first optical structural layer 200) coated with the first optical adhesive layer 510 may be attached to the encapsulation layer 400.

For example, in the display panel according to some other embodiments of the present disclosure, as shown in FIG. 4, the first light shielding pattern 300c is located between the first optical adhesive layer 510c and the optical film (the first optical structural layer 200). Thus, when the display panel is manufactured, the first light shielding pattern 300c may be formed at one side of the optical film, then the first optical adhesive layer 510c is applied to cover the first light shielding pattern 300c, and then the optical film (the first optical structural layer 200) coated with the first optical adhesive layer 510c is attached to the encapsulation layer 400.

For example, in the display panel according to at least one embodiment of the present disclosure, the first optical adhesive layer has a thickness not less than a thickness of the first light shielding pattern. Thus, the first optical adhesive layer can reduce or eliminate the step caused by the first light shielding pattern, which facilitates improvement in planarization of the display panel.

For example, in the display panel according to at least one embodiment of the present disclosure, the thickness of the first optical adhesive layer is at least four times the thickness of the first light shielding pattern. Thus, the first optical adhesive layer (for example, the pressure sensitive adhesive) can eliminate the step caused by the first light shielding pattern to improve the flatness of the display panel.

For example, the first optical adhesive layer has a thickness of 5 to 15 microns, such as 7 microns, 19 microns, 11 microns, 13 microns, or the like. For example, the first light shielding pattern has a thickness of 1 to 4 microns, such as 1.5 microns, 2 microns, 2.5 microns, 3 microns, 3.5 microns, or the like.

For example, in the display panel according to some other embodiment of the present disclosure, the first light shielding pattern is located at a side of the display array layer opposite to the first optical structural layer in the direction perpendicular to the plane where the display array layer is located. Exemplarily, as shown in FIG. 5A, the first light shielding pattern 300d is provided at the side of the display array layer 100 opposite to the first optical structural layer 200, and thus, the first light shielding pattern 300d can absorb the interference light reflected by the first optical structural layer 200. That is, even if entering the second sub-display area, the interference light may be absorbed by the first light shielding pattern 300d.

For example, in the display panel according to at least one embodiment of the present disclosure, a plurality of openings are provided in a portion of the first light shielding pattern, which portion is located in the second sub-display area. Exemplarily, as shown in FIGS. 5A and 5B, the first light shielding pattern 300d includes a plurality of second openings 302, and the ambient light may be transmitted through the display panel through the second openings 302. Thus, the first light shielding pattern 300d may have a large design area; furthermore, the first light shielding pattern 300d can also shield the interference light emitted by the sub-pixel in the second sub-display area 102 and reflected by the first optical structural layer 200, thereby further reducing the amount of the interference light emitted from the back side of the display panel. For example, in the second sub-display area 102, the second openings 302 may be configured to overlap with the spacing area between adjacent sub-pixels, or to overlap with the sub-pixel. For example, in the case where the second openings 302 overlap with the sub-pixel, through holes may be provided at a portion of the reflective layer or the reflective electrode (for example, the anode) in the display array layer overlapping with the second openings 302, so as to transmit the ambient light.

For example, in at least one embodiment of the present disclosure, as shown in FIGS. 3, 4 and 5A, the display panel includes a base 1. Various structures of the display panel (for example, the display array layer 100, the first optical structural layer 200, the first light shielding pattern 300, or the like) are located on the base 1. The side of the display array layer 100 opposite to the base 1 is configured as the display side of the display panel, and the side of the base 1 opposite to the display array layer 100 is configured as the back side of the display panel.

For example, in at least one embodiment of the present disclosure, in the case where the first light shielding pattern is located at the side of the display array layer opposite to the first optical structural layer, as shown in FIG. 5A, the first light shielding pattern 300d may be located at the side of the base 1 opposite to the display array layer 100.

For example, the base 1 may be a glass plate, a quartz plate, a metal plate, a resinous plate, or the like. For example, the base 1 may be made of an organic material, for example, a resinous material, such as polyimide, polycarbonate, polyacrylate, polyetherimide, polyethersulfone, polyethylene terephthalate, polyethylene naphthalate, or the like.

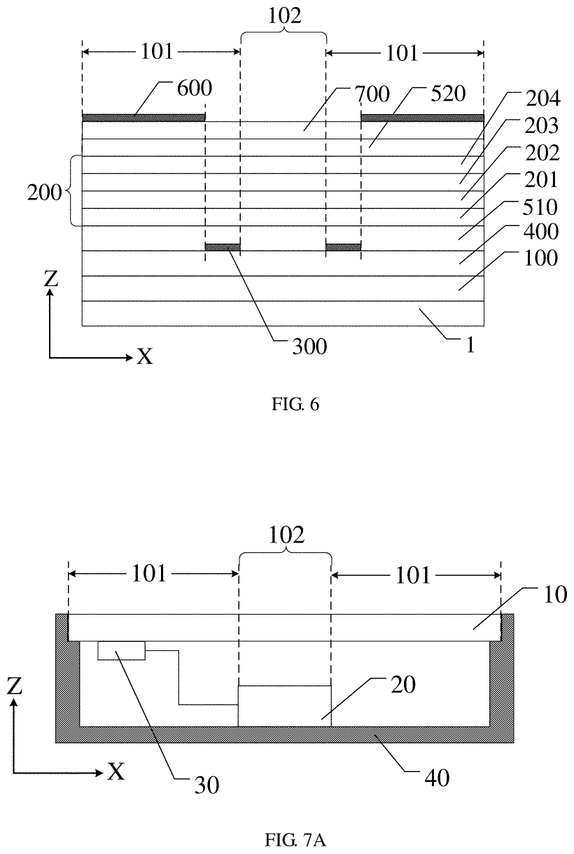

For example, in the display panel according to at least one embodiment of the present disclosure, the optical film includes a quarter-wave plate, a polarizer, or the like. Exemplarily, as shown in FIG. 6, the optical film (the first optical structural layer 200) includes a quarter-wave plate 201 and a polarizer 203. In practical applications, incident light may be partially reflected by the quarter-wave plate 201 and the polarizer 203 during conversion of the polarization state of the light, thereby tending to cause a ghost phenomenon. For example, the ambient light is linearly polarized in one direction after transmitted through the polarizer 203. Assuming that the incident ambient light becomes first linear polarization light with a first polarization direction after passing through the polarizer 203, the first linear polarization light is converted into first circular polarization light (for example, left-handed polarization light) by the quarter-wave plate 201, the first circular polarization light becomes second circular polarization light (for example, right-handed polarization light) after reflected by, for example, the reflective electrode or the reflective layer, the second circular polarization light is converted into second linear polarization light with a second polarization direction by the quarter-wave plate 201, and the first and second polarization directions are perpendicular to each other. Thus, the second linear polarization light is unable to be transmitted through the polarizer 203, such that the ambient light cannot be emitted out from the display side of the display panel after entering the display panel, thereby eliminating the adverse effect of the ambient light on displayed images.

For example, the optical film may further include film layers 201, 204 for protection and support, and the film layers 201, 204 may be made of TAC (cellulose triacetate), for example. For example, the polarizer 203 may be made of a material tending to be shrunk by heat, such as polyvinyl alcohol (PVA), or the like, and the TAC may play a supporting role to prevent shrinkage deformation of the PVA.

For example, in at least one embodiment of the present disclosure, as shown in FIG. 6, the display panel may further include an encapsulation cover plate 700. For example, a second optical adhesive layer 520 may be provided between the encapsulation cover plate 700 and the first optical structural layer 200 to attach the encapsulation cover plate 700 in the display panel. For example, for the material of the encapsulation cover plate 700, reference may be made to the related description of the base in the foregoing embodiments, and description thereof is not repeated herein.

For example, the display panel according to at least one embodiment of the present disclosure further includes a black matrix in addition to the above-mentioned structure, and at least a part of the black matrix is located in the first sub-display area at the side of the first optical structural layer opposite to the display array layer. Exemplarily, as shown in FIG. 6, the black matrix 600 is located in the first sub-display area 101. The black matrix 600 can separate the respective sub-pixels to prevent color mixture, so as to improve contrast of a displayed image. For example, the black matrix 600 is located at a side of the encapsulation cover plate 700 opposite to the first optical structural layer 200. It should be noted that in some examples, the black matrix is only required to be located at the light outgoing side of the display array layer, and a specific position thereof may be designed according to actual needs.

It should be noted that in at least one embodiment of the present disclosure, when the first light shielding pattern is as shown in FIG. 2B, the portion of the first light shielding pattern, which portion is located in the second sub-display area, may also have an effect of separating the sub-pixels to prevent color mixture, and therefore, even if the black matrix is not provided in the second sub-display area, the effect of a displayed image on the display panel is not affected adversely.

For example, in at least one embodiment of the present disclosure, the display panel may further include a touch structure in addition to the above-mentioned structure, so as to have a touch function.

For example, in at least one embodiment of the present disclosure, a light splitting element (for example, a light splitting grating, or the like) may be provided at the display side of the display panel, such that the display panel may have a three-dimensional display function.

For example, the display panel may be configured as any product or component having a display function, such as a television, a digital camera, a mobile phone, a watch, a tablet computer, a notebook computer, a navigator, or the like.

It should be noted that for clarity, not all structures of the above-mentioned display substrate and the display panel including the display substrate are described. Other structures may be provided by those skilled in the art according to specific application scenarios to achieve necessary functions of the display substrate and the display panel, which is not limited in the embodiments of the present disclosure.

At least one embodiment of the present disclosure provides a display device including the display panel according to any one of the above-mentioned embodiments.

For example, the display device according to at least one embodiment of the present disclosure further includes an image taking device located at the side of the display panel opposite to the display side; and at a plane where the display panel is located, an orthographic projection of the second sub-display area of the display panel at least partially overlaps with an orthographic projection of the image taking device. For example, in the embodiment of the present disclosure, the orthographic projection of the second sub-display area may partially overlap with the orthographic projection of the image taking device, or the orthographic projection of the second sub-display area may coincide with the orthographic projection of the image taking device, or the orthographic projection of the image taking device may be located within the orthographic projection of the second sub-display area. Correspondingly, for example, in the display device, the second sub-display area has a transmittance greater than 20%, such as greater than 50%, 70%, 90%, or the like, thereby correspondingly allowing the image with a desired quality to be taken by the image taking device.

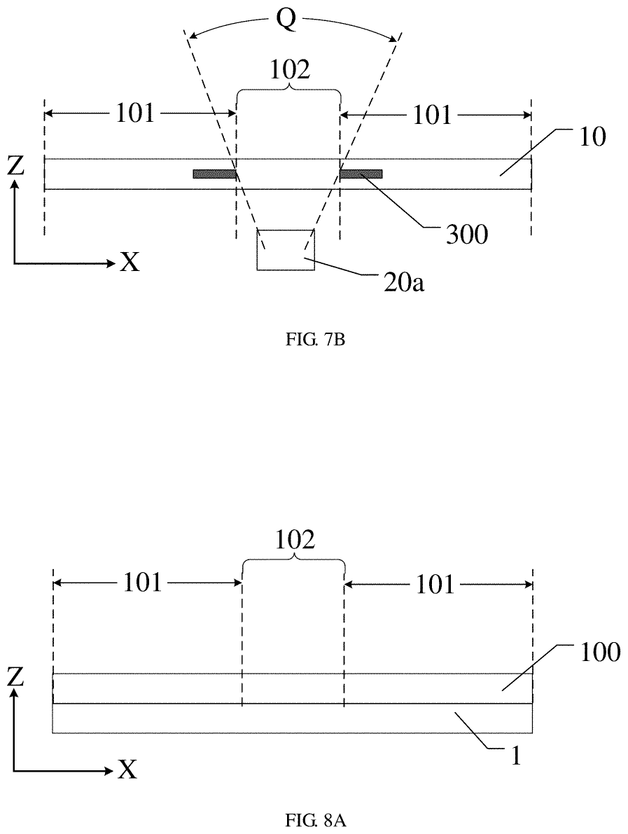

For example, in some embodiments of the present disclosure, as shown in FIG. 7A, the image taking device 20 is provided at the back side of the display panel 10 (refer to the foregoing related description of the embodiments of the display panel), and the orthographic projection of the image taking device 20 (for example, a lens assembly thereof, or the like) at the display panel 10 coincides with the second sub-display area 102. That is, the image taking device 20 has the same planar shape as the second sub-display area 102. For example, in the case where an orthographic projection of the second sub-display area 102 at the X-Y plane is circular, the image taking device 20 also has a circular orthographic projection at the X-Y plane as well, and the two orthographic projections coincide with each other. In conjunction with the related description of the structure of the display panel 10 in the foregoing embodiments, the ambient light may enter the image taking device 20 through the second sub-display area 102, and the interference light generated in the display panel can be shielded by the first light shielding pattern. That is, the interference light may not be emitted into the image taking device or a small amount of interference light is emitted into the image taking device, thereby improving the quality of the image of the image taking device (for example, a camera).

For example, in the case where a position relationship between the second sub-display area and the image taking device is as shown in FIG. 7A, the image taking device may have a diameter of 1 to 5 mm, for example, 1 to 3 mm. For example, both the second sub-display area and the image taking device have a diameter of 2 mm. It should be noted that the size of the image taking device may be selected as required, and is not limited to the above-mentioned range.

For example, the camera of the image taking device includes a lens assembly and an image sensor, the lens assembly may have a focusing function, and along a path of light emitted into the camera from the outside, the lens assembly of the camera may include a first convex lens, a concave lens and a second convex lens which are arranged sequentially. The ambient light is transmitted through the lens assembly into the image sensor, and an imaging focal length of the lens assembly may be adjusted with a distance between the lenses and/or a focal length of each lens, thereby shooting a long-range view image or a close-range view image. It should be noted that types and combinations of the lenses in the lens assembly may be set as required, and are not limited to the above-mentioned selections.

For example, the image sensor can convert an image signal taken by the camera into an electrical signal to be transmitted to other components. For example, the image sensor may be of a complementary metal oxide semiconductor (CMOS) type or a charge coupled device (CCD) type, and for example, includes imaging sub-pixels arranged in an array. For example, the other component may be configured as a control chip of the display device, and for example, after the electrical signal from an image processing component is processed by the control chip, a relevant instruction may be sent to the display panel, such that the display panel can display an environmental image taken by the camera.

Exemplarily, as shown in FIG. 7A, the control chip 30 may be coupled with the display panel 10 and the image taking device 20 to control functions of the display panel 10 and the image taking device 20. For example, the control chip 30 may be provided at a flexible circuit board which may be fixed on the display panel 10 in a binding manner, so as to implement signal connection between the control chip 30 and a circuit in the display panel 10. For example, the control chip 30 may be fixed to a back surface of the display panel 10.

For example, the control chip may be a central processing unit, a digital signal processor, a single chip microcomputer, a programmable logic controller, or the like. For example, the control chip may further include a memory, a power module, or the like, and achieve power supply and signal input-output functions through wires, signal lines, or the like, which are provided additionally. For example, the control chip may further include a hardware circuit, a computer executable code, or the like. The hardware circuit may include a conventional very-large-scale integration (VLSI) circuit or a gate array, an existing semiconductor components, such as a logic chip and a transistor, or other discrete components, and may further include a field programmable gate array, a programmable array logic, a programmable logic apparatus, or the like.

For example, in at least one embodiment of the present disclosure, as shown in FIG. 7A, the display device includes a back-plate supporting structure 40 located at the back side of the display panel 10, and the image taking device 20 is fixed on the back-plate supporting structure 40 and located between the back-plate supporting structure 40 and the display panel 10. The back-plate supporting structure 40 may support the display panel 10 to protect the display panel. For example, the back-plate supporting structure 40 may serve as a casing of the display device.

For example, in some embodiments of the present disclosure, as shown in FIGS. 1A and 7B, an image taking device 20a is provided at the back side of the display panel 10 (referring to the related description of the foregoing embodiments of the display panel), and the orthographic projection of the image taking device 20a (for example, the lens assembly therein, or the like) at the display panel 10 is located within the second sub-display area 102. For the structure of the display panel 10, reference may be made to the related description of the embodiment shown in FIG. 1B, and thus, the image taking device 20a may have a large viewing angle Q to increase the image taking range of the image taking device 20a. For example, the image taking device 20 has a similar planar shape to the second sub-display area 102. For example, as shown in FIG. 1A, in the case of the circular orthographic projection of the second sub-display area 102 at the X-Y plane, the image taking device 20 also has the circular orthographic projection at the X-Y plane, and the two circles may be concentric.

For example, in the case where the position relationship between the second sub-display area and the image taking device is as shown in FIGS. 1A and 7B, the image taking device may have a diameter of about 1 to 4 mm, and the second sub-display area may have a diameter of 1 to 5 mm. For example, the diameters of the image taking device and the second sub-display area have a difference by at least 1 mm. For example, the image taking device may have a diameter of about 1 to 2 mm, and the second sub-display area may have a diameter of 2 to 3 mm. It should be noted that the size of the image taking device may be selected as required, and is not limited to the above-mentioned range.

At least one embodiment of the present disclosure provides a manufacturing method of a display panel. The manufacturing method of a display panel includes: forming a display array layer comprising a first sub-display area and a second sub-display area at least partially surrounded by the first sub-display area, wherein the second sub-display area is formed to be able to transmit ambient light; forming a first optical structural layer at a display side of the display array layer; and forming a first light shielding pattern at a side of the first optical structural layer facing the display array layer, wherein the first light shielding pattern is formed to at least partially surround the second sub-display area and expose at least a part thereof. For the structure of the display panel obtained with the above-mentioned method, reference may be made to the related description in the foregoing embodiments (for example, the embodiments shown in FIGS. 1B, 2A, 3, 4 and 5), and description thereof is not repeated herein.

For example, in the manufacturing method of the display panel according to at least one embodiment of the present disclosure, the formed display array layer includes the plurality of spaced sub-pixels, and formation of the first light shielding pattern includes: forming the net-shaped light shielding bar in the second sub-display area, wherein at the plane where the display array layer is located, the orthogonal projection of the net-shaped portion of the light shielding bar coincides with the orthogonal projection of the spacing area between adjacent sub-pixels, and the orthogonal projection of the mesh hole of the light shielding bar coincides with the orthogonal projection of the sub-pixel. In the display panel obtained with the method, the first light shielding pattern has a large area; furthermore, the first light shielding pattern can also shield the interference light emitted by the sub-pixel in the second sub-display area and reflected by the first optical structural layer, thereby further reducing the amount of the interference light emitted from the back side of the display panel. For the structure of the display panel obtained with the method, reference may be made to the related description in the embodiments as shown in FIGS. 2A and 2B, and description thereof is not repeated herein.

For example, the manufacturing method of the display panel according to at least one embodiment of the present disclosure further includes: forming the encapsulation layer at a surface of the display side of the display array layer, wherein the encapsulation layer is located between the display array layer and the first optical structural layer. In the display panel obtained with the method, the encapsulation layer covers the display array layer to protect the structures therein, such as the light-emitting device, or the like. For the structure of the display panel obtained with the method, reference may be made to the related description in the embodiments as shown in FIGS. 3 and 4, and description thereof is not repeated herein.

For example, in the manufacturing method of the display panel according to some embodiments of the present disclosure, forming the first light shielding pattern includes: applying a light shielding material on the encapsulation layer to form the first light shielding pattern, and then providing the first optical adhesive layer to attach the first optical structural layer on the encapsulation layer.

For example, in the manufacturing method of the display panel according to some other embodiments of the present disclosure, forming the first light shielding pattern includes: applying a light shielding material at one side of the optical structural layer to form the first light shielding pattern, and then providing the first optical adhesive layer to attach the first optical structural layer on the encapsulation layer. In the display panel obtained with the above-mentioned method, the encapsulation layer can prevent harmful substances in the first light shielding pattern (for example, the first light shielding pattern is made of ink) from intruding into the display array layer. For the structure of the display panel obtained with the method, reference may be made to the related description in the embodiments as shown in FIGS. 3 and 4, and description thereof is not repeated herein.

For example, in the manufacturing method of the display panel according to at least one embodiment of the present disclosure, the method of applying the light shielding material includes a screen printing method. The screen printing method has a simple technology, and the formed first light shielding pattern has a small thickness. For example, the light shielding material includes a light absorbing material, for example, ink. It should be noted that a manufacturing technology of the first light shielding pattern may be selected as required, and is not limited herein. For example, a light shielding material film may be deposited on the encapsulation layer and then subjected to a patterning technology to form the first light shielding pattern. For example, the patterning technology may include a photolithographic patterning technology.

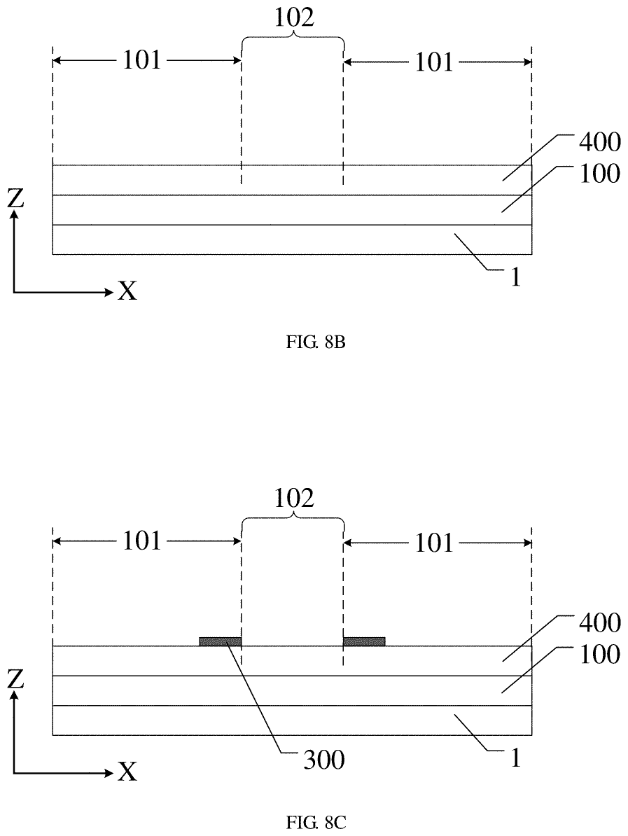

Hereinafter, in one example of the present disclosure, as shown in FIGS. 8A-8C, the manufacturing method of the display panel will be described with the manufacturing process of the display panel as shown in FIG. 3.

As shown in FIG. 8A, the base 1 is provided, and the display array layer 100 is formed on the base 1. Forming the display array layer 100 may include forming the drive circuit layer (including a thin film transistor, or the like) on the base 1 and then manufacturing the light-emitting device array on the drive circuit layer. For the structures of the drive circuit layer and the light-emitting device, reference may be made to the related description in the foregoing embodiments, and the specific manufacturing technology thereof may be selected according to a conventional technology, which is not repeated herein.

As shown in FIGS. 8A to 8B, the encapsulation layer 400 is formed on the display array layer 100 and covers the display array layer 100. For example, an inorganic material may be deposited on the display array layer 100 to form the first inorganic encapsulation layer, then an organic material is applied to form the organic encapsulation layer, and then an inorganic material is deposited on the organic encapsulation layer to form the second inorganic encapsulation layer. For example, the organic encapsulation layer may be formed with an inkjet printing method, and thus may play a planarization role to improve the flatness of the display panel.

As shown in FIGS. 8B to 8C, a light shielding material is applied on the display array layer 100 with the screen printing technology to form the first light shielding pattern 300. For example, the first light shielding pattern 300 may have a shape as shown in FIG. 1C.

As shown in FIG. 8C to FIG. 3, the first optical structural layer 200 (for example, the optical film) coated with the first optical adhesive layer 510 on a surface thereof is provided and then attached to the encapsulation layer 400 using the first optical adhesive layer 510, and the first light shielding pattern 300 is covered with the first optical structural layer 200.

The following statements should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness and size of a layer or a structure may be enlarged. However, it should be understood that, in the case in which a component or element such as a layer, film, area, substrate or the like is referred to be “on” or “under” another component or element, it may be directly on or under the another component or element or a component or element is interposed therebetween.

(3) In case of no conflict, features in one embodiment or in different embodiments can be combined.

What are described above is related to the illustrative embodiments of the disclosure only and not limitative to the scope of the disclosure; the scopes of the disclosure are defined by the accompanying claims.

1: A display panel, comprising:
a display array layer comprising a first sub-display area and a second sub-display area at least partially surrounded by the first sub-display area, the second sub-display area being configured to be able to transmit ambient light;
a first optical structural layer located at a display side of the display array layer; and
a first light shielding pattern located at a side of the first optical structural layer facing the display array layer, wherein the first light shielding pattern at least partially surrounds the second sub-display area and exposes at least a part of the second sub-display area.

2: The display panel according to claim 1, wherein
the first light shielding pattern is located between the display array layer and the first optical structural layer in a direction perpendicular to a plane where the display array layer is located.

3: The display panel according to claim 2, wherein
the display array layer comprises a plurality of sub-pixels spaced apart from each other; and
the first light shielding pattern at least partially overlaps with a spacing area between adjacent sub-pixels in the direction perpendicular to the plane where the display array layer is located.

4: The display panel according to claim 3, wherein
in the second sub-display area, the first light shielding pattern further comprises a net-shaped light shielding bar; and
at the plane where the display array layer is located, an orthogonal projection of a net-shaped portion of the light shielding bar coincides with an orthogonal projection of the spacing area between adjacent sub-pixels, and an orthogonal projection of a mesh hole of the light shielding bar coincides with an orthogonal projection of the sub-pixel.

5: The display panel according to claim 1, wherein the first optical structural layer comprises an optical film.

6: The display panel according to claim 5, wherein the optical film comprises a quarter-wave plate and/or a polarizer.

7: The display panel according to claim 5, further comprising:
an encapsulation layer located between the display array layer and the first optical structural layer
wherein the first light shielding pattern is located between the encapsulation layer and the first optical structural layer, or located between the display array layer and the encapsulation layer.

8: The display panel according to claim 7, further comprising:
a first optical adhesive layer located between the encapsulation layer and the optical film;
wherein the first light shielding pattern is located between the first optical adhesive layer and the encapsulation layer, or located between the first optical adhesive layer and the optical film.

9: The display panel according to claim 8, wherein the first optical adhesive layer has a thickness not less than a thickness of the first light shielding pattern.

10: The display panel according to claim 9, wherein the thickness of the first optical adhesive layer is at least four times the thickness of the first light shielding pattern.

11: The display panel according to claim 1, wherein the first light shielding pattern is located at a side of the display array layer opposite to the first optical structural layer in a direction perpendicular to the plane where the display array layer is located.

12: The display panel according to claim 11, wherein a plurality of openings are provided in a portion of the first light shielding pattern, which portion is located in the second sub-display area.

13: The display panel according to claim 1, further comprising a black matrix,
wherein at least a part of the black matrix is located in the first sub-display area at a side of the first optical structural layer opposite to the display array layer.

14: A display device, comprising a display panel, wherein the display panel comprises:
a display array layer comprising a first sub-display area and a second sub-display area at least partially surrounded by the first sub-display area, the second sub-display area being configured to be able to transmit ambient light;
a first optical structural layer located at a display side of the display array layer; and
a first light shielding pattern located at a side of the first optical structural layer facing the display array layer, wherein the first light shielding pattern at least partially surrounds the second sub-display area and exposes at least a part of the second sub-display area.

15: The display device according to claim 14, further comprising an image taking device, wherein the image taking device is located at a side of the display panel opposite to the display side; and
at a plane where the display panel is located, an orthographic projection of the second sub-display area of the display panel at least partially overlaps with an orthographic projection of the image taking device.

16: A manufacturing method of a display panel, comprising:
forming a display array layer comprising a first sub-display area and a second sub-display area at least partially surrounded by the first sub-display area, wherein the second sub-display area is formed to be able to transmit ambient light;
forming a first optical structural layer at a display side of the display array layer; and
forming a first light shielding pattern at a side of the first optical structural layer facing the display array layer, wherein the first light shielding pattern is formed to at least partially surround the second sub-display area and expose at least a part thereof.

17: The manufacturing method according to claim 16, wherein the formed display array layer comprises a plurality of spaced sub-pixels, and forming the first light shielding pattern comprises:
forming a net-shaped light shielding bar in the second sub-display area;
wherein at a plane where the display array layer is located, an orthogonal projection of a net-shaped portion of the light shielding bar coincides with an orthogonal projection of a spacing area between adjacent sub-pixels, and an orthogonal projection of a mesh hole of the light shielding bar coincides with an orthogonal projection of the sub-pixel.

18: The manufacturing method according to claim 16, further comprising:
forming an encapsulation layer at a surface of the display side of the display array layer;
wherein the encapsulation layer is located between the display array layer and the first optical structural layer.

19: The manufacturing method according to claim 18, wherein forming the first light shielding pattern comprises:
applying a light shielding material on the encapsulation layer to form the first light shielding pattern, and then providing a first optical adhesive layer to attach the first optical structural layer on the encapsulation layer; or
applying a light shielding material at a side of the first optical structural layer to form the first light shielding pattern, and then providing a first optical adhesive layer to attach the first optical structural layer on the encapsulation layer.

20: The manufacturing method according to claim 19, wherein a method of applying the light shielding material comprises a screen printing method.
